(19) United States
(12) Patent Application Publication
(10) Pub. No.: US 2017/0170039 A1
(43) Pub. Date: Jun. 15, 2017

(54) LIGHT IRRADIATION TYPE HEAT TREATMENT APPARATUS

(71) Applicant: SCREEN Holdings Co., Ltd., Kyoto (JP)

(72) Inventors: Takayuki AOYAMA, Kyoto-shi (JP); Masashi FURUKAWA, Kyoto-shi (JP)

(21) Appl. No.: 15/358,278

(22) Filed: Nov. 22, 2016

(30) Foreign Application Priority Data
Dec. 11, 2015 (JP) JP2015-241770

(51) Int. Cl. H01L 21/67; H01L 21/225; H01J 61/54; G01N 27/407; H01J 61/16

(52) U.S. Cl. CPC H01L 21/67115; G01N 27/4073; H01J 61/16; H01J 61/547; H01L 21/2253; H01L 21/67242; H01L 21/67017

(57) ABSTRACT

An oxygen concentration measuring chamber is provided on a wall surface of a chamber in which flash lamp annealing is performed, and a zirconia type oxygen analyzer is provided in the oxygen concentration measuring chamber. An opening for bringing the interior space of the oxygen concentration measuring chamber and a heat treatment space of the chamber into communication with each other therethrough is opened and closed by a gate valve. The opening is closed when the pressure in the chamber is reduced during the treatment. When the pressure in the chamber is reduced to a predetermined pressure to enter a stable state, the gate valve opens the opening, so that gas molecules in the chamber are diffused into the oxygen concentration measuring chamber, and the oxygen analyzer measures the concentration of oxygen in the atmosphere in the chamber. A reference gas for use in the measurement has an oxygen concentration of 1 to 100 ppm.

### BACKGROUND OF THE INVENTION

Field of the Invention

The present invention relates to a heat treatment apparatus which irradiates a thin plate-like precision electronic substrate (hereinafter referred to simply as a “substrate”) of silicon such as a semiconductor wafer with a flash of light to heat the substrate.

Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, for example, typically for the activation of impurities implanted in a semiconductor wafer. The irradiation of a surface of a semiconductor wafer implanted with impurities by an ion implantation process with a flash of light from flash lamps allows the temperature rise to an activation temperature only in the surface of the semiconductor wafer in an extremely short time, thereby achieving only the activation of impurities without deep diffusion of the impurities.

The problem of oxidation is encountered not only in the flash lamp annealing but also in heat treatment for heating a semiconductor wafer. It is hence important to control the concentration of oxygen in a chamber that receives a semiconductor wafer therein. In Japanese Patent Application Laid-Open No. 2006-269596, it is disclosed that an oxygen analyzer is provided in a chamber of a heat treatment apparatus including flash lamps to measure the concentration of oxygen during the treatment. In general, it is more preferable that the concentration of oxygen in a chamber is lower for the purpose of preventing oxidation during heating treatment.

It has also been under consideration to apply the flash lamp annealing to the heat treatment of a semiconductor wafer on which a high dielectric constant film (high-k film) made of a material (high dielectric constant material) having a dielectric constant higher than that of silicon dioxide (SiO₂) is formed as a gate insulator film for a field-effect transistor (FET). For the purpose of solving the problem of the increase in leakage current with the reduction in thickness of the gate insulator film, the high dielectric constant film has been developed as a new stacked structure together with a metal gate electrode in which metal is used as the material of a gate electrode. When the flash lamp annealing is applied to the heat treatment of such a high dielectric constant gate insulator film, a lower oxygen concentration environment than ever is required to suppress the increase in the thickness of an oxide film.

For this reason, the conventional flash lamp annealing has been performed at ordinary pressure. However, the flash lamp annealing in a reduced-pressure atmosphere is under consideration. When the flash lamp annealing is performed in a reduced-pressure atmosphere, the pressure in the chamber is repeatedly varied significantly between the ordinary pressure and the reduced pressure.

Unfortunately, when significant pressure variations are repeated in the chamber, the oxygen analyzer simply provided in the chamber as disclosed in Japanese Patent Application Laid-Open No. 2006-269596 causes a problem that the oxygen concentration cannot be measured precisely for the following reasons. One of the reasons lies in that, when the oxygen analyzer is in particular provided near the path of an exhaust system, there are cases in which a backflow (back diffusion) from the exhaust system raises the oxygen concentration around the oxygen analyzer. Another reason lies in that, when an oxygen analyzer operating at high temperature (for example, a high-precision zirconia type oxygen analyzer) is used, the repetition of the pressure reduction and the pressure return in the chamber causes a large airflow around the oxygen analyzer to vary the temperature of the oxygen analyzer itself. As a result, the oxygen analyzer fails to measure the oxygen concentration precisely.

### SUMMARY OF THE INVENTION

The present invention is intended for a heat treatment apparatus for irradiating a substrate with a flash of light to heat the substrate.

According to one aspect of the present invention, the heat treatment apparatus comprises: a chamber for receiving a substrate therein; a flash lamp for irradiating the substrate received in the chamber with a flash of light; a first exhaust part for exhausting an atmosphere from the chamber; a treatment gas supply part for supplying a predetermined treatment gas to the chamber; a measuring chamber provided on a wall surface of the chamber; a zirconia type oxygen analyzer provided in the measuring chamber; a gate valve for opening and closing an opening for bringing the interior of the measuring chamber and the interior of the chamber into communication with each other therethrough; and a controller for controlling the opening and closing of the gate valve, the controller being configured to open the gate valve when the pressure in the chamber is in a stable state.

Even when significant pressure variations are repeated in the chamber, the influence of the pressure variations is blocked by the gate valve, so that the concentration of oxygen in the chamber is precisely measured.

Preferably, the heat treatment apparatus further comprises a reference gas supply part for supplying a reference gas having an oxygen concentration of 1 to 100 ppm to the zirconia type oxygen analyzer.

This allows the limit of measurement of the zirconia type oxygen analyzer to become a lower oxygen concentration.

Preferably, the heat treatment apparatus further comprises: a calibration gas supply part for supplying a gas having the same oxygen concentration as the reference gas to the measuring chamber; and a second exhaust part for exhausting an atmosphere from the measuring chamber.

This achieves the zero point setting of the zirconia type oxygen analyzer.

Preferably, the heat treatment apparatus further comprises a moving mechanism for moving the zirconia type oxygen analyzer into and out of the chamber when the gate valve is open.

Thus, the oxygen concentration in the chamber is measured more directly near the substrate.

It is therefore an object of the present invention to precisely measure the concentration of oxygen even when significant pressure variations are repeated in a chamber.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus according to the present invention;

FIG. 2 is a perspective view showing the entire external appearance of a holder;

FIG. 3 is a top plan view of the holder;

FIG. 4 is a side view of the holder as seen from one side;

FIG. 5 is a plan view of a transfer mechanism;

FIG. 6 is a side view of the transfer mechanism;

FIG. 7 is a plan view showing an arrangement of halogen lamps;

FIG. 8 is a view showing a configuration of an oxygen concentration measuring chamber;

FIG. 9 is a view of an opening left open; and

FIG. 10 is a view showing another configuration of the oxygen concentration measuring chamber.

### DESCRIPTION OF THE PREFERRED EMBODIMENTS

A preferred embodiment according to the present invention will now be described in detail with reference to the drawings.

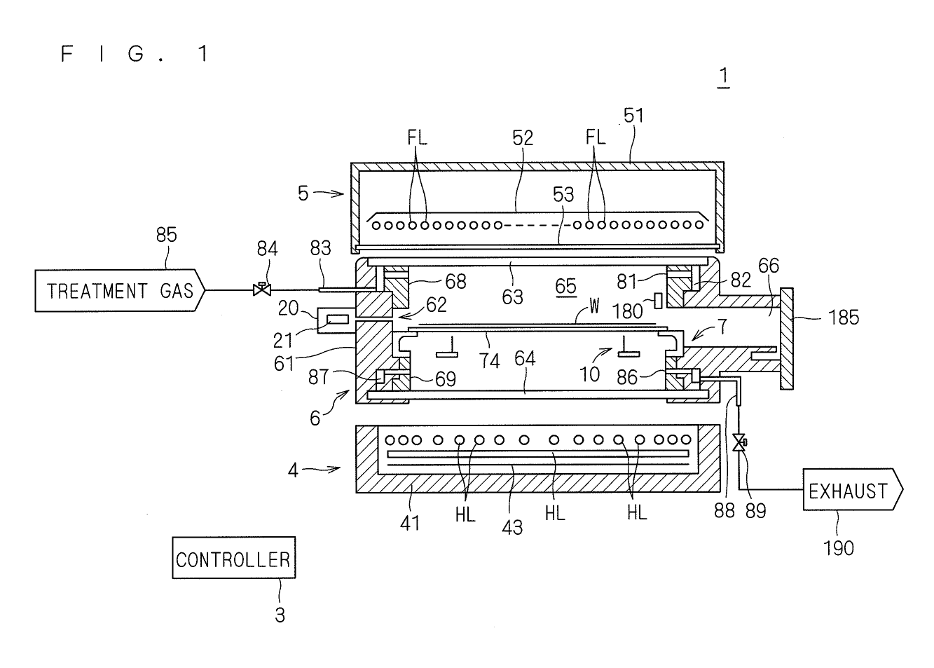

FIG. 1 is a longitudinal sectional view showing a configuration of a heat treatment apparatus 1 according to the present invention. The heat treatment apparatus 1 according to the present preferred embodiment is a flash lamp annealer for irradiating a disk-shaped semiconductor wafer W serving as a substrate with a flash of light to heat the semiconductor wafer W. The size of the semiconductor wafer W to be treated is not particularly limited. For example, the semiconductor wafer W to be treated has a diameter of 300 mm and 450 mm. A high dielectric constant film, for example, is formed on the semiconductor wafer W prior to the transport into the heat treatment apparatus 1, and the heat treatment apparatus 1 performs a heating treatment on the semiconductor wafer W to thereby perform PDA (post deposition annealing) on the high dielectric constant film. It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes an oxygen concentration measuring chamber 20 provided on a wall surface of the chamber 6 and including a built-in oxygen analyzer 21 to measure the concentration of oxygen in the chamber 6. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits a flash of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6. The upper chamber window 63 and the lower chamber window 64 have a thickness of approximately 28 mm, for example.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W.

The chamber side portion 61 and the upper and lower reflective rings 68 and 69 are made of a metal material (e.g., stainless steel) with high strength and high heat resistance. The inner peripheral surfaces of the upper and lower reflective rings 68 and 69 are provided as mirror surfaces by electrolytic nickel plating.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

At least one gas supply opening 81 for supplying a treatment gas (in this preferred embodiment, nitrogen (N₂) gas) therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. The treatment gas supply source 85 feeds nitrogen gas as the treatment gas to the gas supply pipe 83 under the control of the controller 3. A valve 84 is inserted at some midpoint in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. It should be noted that the treatment gas is not limited to nitrogen gas, but may be inert gases such as argon (Ar) and helium (He), and reactive gases such as oxygen (O₂), hydrogen (H₂), heavy hydrogen (D₂), ammonia (NH₃), chlorine (Cl₂), hydrogen chloride (HCl) and ozone (O₃).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part (first exhaust part) 190. A valve 89 is inserted at some midpoint in the gas exhaust pipe 88. When the valve 89 is opened, the gas in the heat treatment space 65 is exhausted through the gas exhaust opening 86 and the buffer space 87 to the gas exhaust pipe 88. When the valve 89 is opened to only exhaust the gas from the heat treatment space 65 while the valve 84 is closed so as not to supply the treatment gas into the heat treatment space 65, the pressure in the heat treatment space 65 of the chamber 6 is reduced to less than atmospheric pressure. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. The treatment gas supply source 85 and the exhaust part 190 may be mechanisms provided in the heat treatment apparatus 1 or be utility systems in a factory in which the heat treatment apparatus 1 is installed.

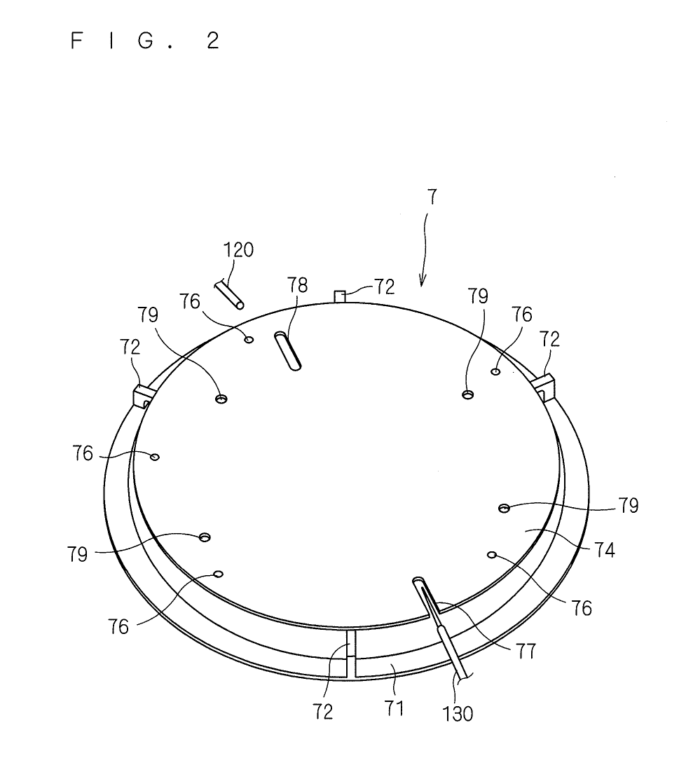

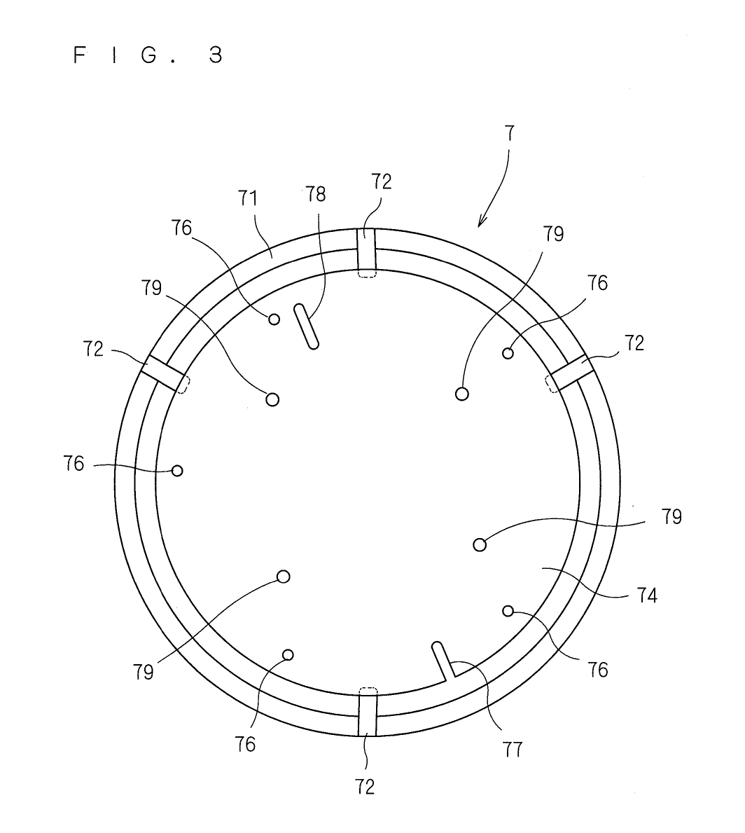

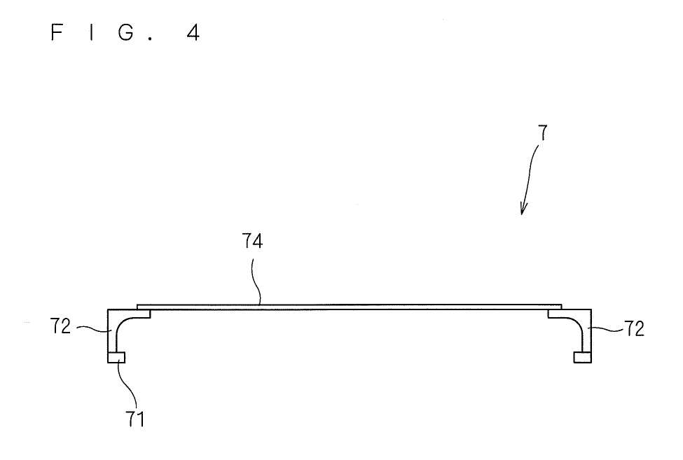

FIG. 2 is a perspective view showing the entire external appearance of the holder 7. FIG. 3 is a top plan view of the holder 7. FIG. 4 is a side view of the holder 7 as seen from one side. The holder 7 includes a base ring 71, coupling portions 72, and a susceptor 74. The base ring 71, the coupling portions 72, and the susceptor 74 are all made of quartz. In other words, the whole of the holder 7 is made of quartz.

The base ring 71 is a quartz member in the form of an annular ring. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 in the form of the annular ring and arranged in a circumferential direction of the base ring 71. The coupling portions 72 are quartz members, and are rigidly secured to the base ring 71 by welding. The base ring 71 may be of an arcuate shape such that a portion is removed from the annular ring.

The susceptor 74 having a planar shape is supported by the four coupling portions 72 provided on the base ring 71. The susceptor 74 is a generally circular planar member made of quartz. The diameter of the susceptor 74 is greater than that of a semiconductor wafer W. In other words, the susceptor 74 has a size, as seen in plan view, greater than that of the semiconductor wafer W. Multiple (in the present preferred embodiment, five) guide pins 76 are mounted upright on the upper surface of the susceptor 74. The five guide pins 76 are disposed along the circumference of a circle concentric with the outer circumference of the susceptor 74. The diameter of a circle on which the five guide pins 76 are disposed is slightly greater than the diameter of the semiconductor wafer W. The guide pins 76 are also made of quartz. The guide pins 76 may be machined from a quartz ingot integrally with the susceptor 74. Alternatively, the guide pins 76 separately machined may be attached to the susceptor 74 by welding and the like.

The four coupling portions 72 provided upright on the base ring 71 and the lower surface of a peripheral portion of the susceptor 74 are rigidly secured to each other by welding. In other words, the susceptor 74 and the base ring 71 are fixedly coupled to each other with the coupling portions 72, and the holder 7 is an integrally formed member made of quartz. The base ring 71 of such a holder 7 is supported by the wall surface of the chamber 6, whereby the holder 7 is mounted to the chamber 6. With the holder 7 mounted to the chamber 6, the susceptor 74 of a generally disk-shaped configuration assumes a horizontal attitude (an attitude such that the normal to the susceptor 74 coincides with a vertical direction). A semiconductor wafer W transported into the chamber 6 is placed and held in a horizontal attitude on the susceptor 74 of the holder 7 mounted to the chamber 6. The semiconductor wafer W is placed inside the circle defined by the five guide pins 76. This prevents the horizontal misregistration of the semiconductor wafer W. The number of guide pins 76 is not limited to five, but may be determined so as to prevent the misregistration of the semiconductor wafer W.

As shown in FIGS. 2 and 3, an opening 78 and a notch 77 are provided in the susceptor 74 so as to extend vertically through the susceptor 74. The notch 77 is provided to allow a distal end portion of a probe of a contact-type thermometer 130 including a thermocouple to pass therethrough. The opening 78, on the other hand, is provided for a radiation thermometer 120 to receive radiation (infrared radiation) emitted from the lower surface of the semiconductor wafer W held by the susceptor 74. The susceptor 74 further includes four through holes 79 bored therein and designed so that lift pins 12 of the transfer mechanism 10 to be described later pass through the through holes 79, respectively, to transfer a semiconductor wafer W.

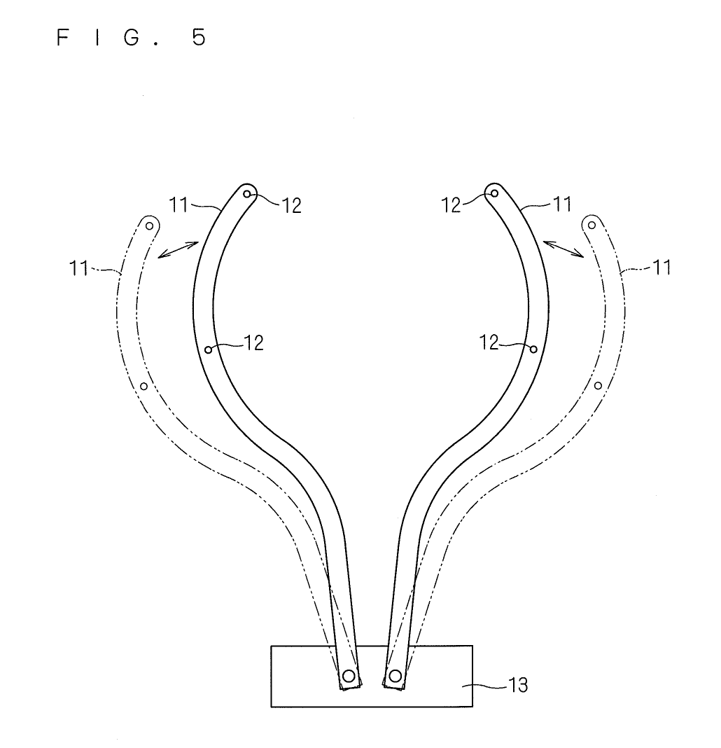

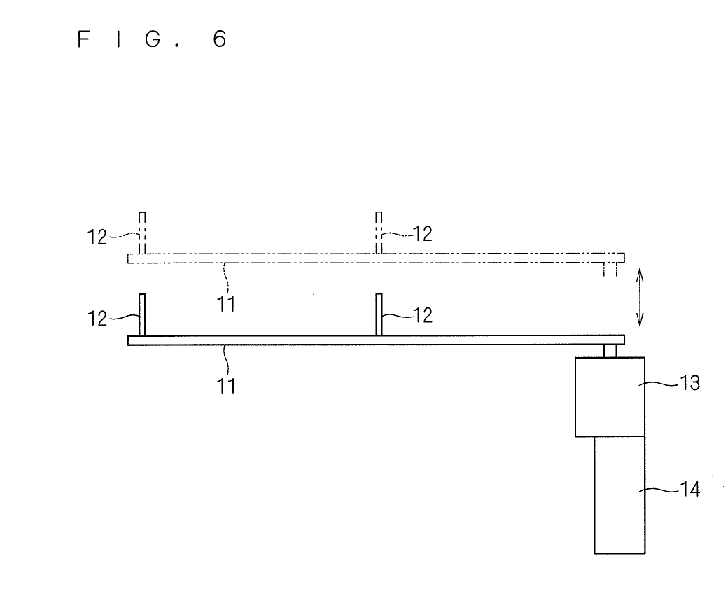

FIG. 5 is a plan view of the transfer mechanism 10. FIG. 6 is a side view of the transfer mechanism 10. The transfer mechanism 10 includes a pair of transfer arms 11. The transfer arms 11 are of an arcuate configuration extending substantially along the annular recessed portion 62. Each of the transfer arms 11 includes the two lift pins 12 mounted upright thereon. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74 so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62.

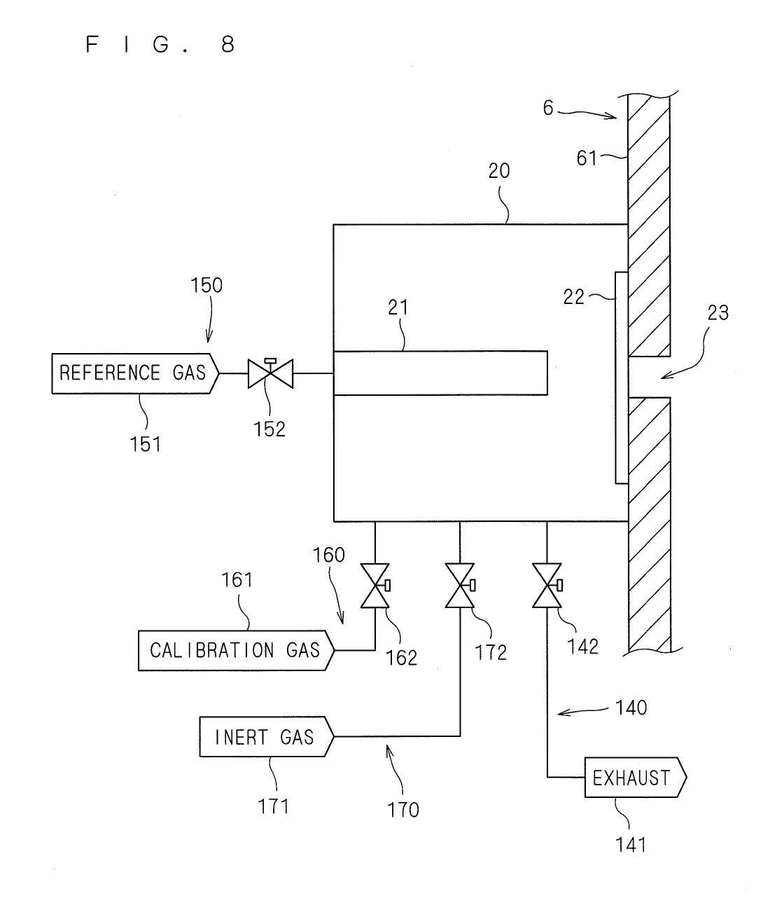

The oxygen concentration measuring chamber 20 is attached to the chamber side portion 61 that is a side wall of the chamber 6. FIG. 8 is a view showing a configuration of the oxygen concentration measuring chamber 20. The oxygen concentration measuring chamber 20 is provided fixedly on an outer wall surface of the chamber side portion 61. The oxygen concentration measuring chamber 20 includes the oxygen analyzer 21 incorporated in the interior space thereof. The oxygen analyzer 21 in this preferred embodiment is a zirconia type oxygen analyzer employing stabilized zirconia. The stabilized zirconia is obtained by adding yttria (Y₂O₃) serving as a stabilizer to zirconia (ZrO₂). The stabilized zirconia is excellent in ionic conductivity, and becomes a solid electrolyte at high temperatures. When there is a difference in oxygen concentration between opposite sides of the zirconia solid electrolyte at high temperatures, oxygen ions (O²⁻) are produced on the high oxygen concentration side by a reduction reaction. The oxygen ions move in the zirconia solid electrolyte, and are turned into oxygen (O₂) on the low oxygen concentration side by an oxidation reaction. The transfer of electrons in the oxidation and reduction reactions on the opposite sides of the zirconia solid electrolyte produces an electromotive force. The magnitude of the electromotive force is determined by the difference in oxygen concentration. Thus, the electromotive force is measured when a gas to be measured is brought into contact with one side of the zirconia solid electrolyte at high temperature while a reference gas having a known oxygen concentration is in contact with the opposite side thereof. This achieves a measurement of the oxygen concentration in the gas to be measured. The zirconia type oxygen analyzer 21 according to the present preferred embodiment uses such a principle to measure the concentration of oxygen in the chamber 6.

The oxygen analyzer 21 includes electrodes mounted to the inner and outer surfaces of the stabilized zirconia having a tubular shape with a bottom, and a heater for heating the stabilized zirconia (both not shown). A reference gas having a known oxygen concentration is supplied from a reference gas supply part 150 to be described later to the inside of the tubular portion of the stabilized zirconia heated to high temperatures by the heater. The atmosphere inside the chamber 6 is introduced to the outside of the tubular portion of the stabilized zirconia. The oxygen analyzer 21 measures the magnitude of the electromotive force between the electrodes mounted to the inner and outer surfaces of the stabilized zirconia to measure the concentration of oxygen in the atmosphere inside the chamber 6.

The chamber side portion 61 includes an opening 23 formed therein for communication between the interior space of the oxygen concentration measuring chamber 20 and the heat treatment space 65 of the chamber 6. The oxygen concentration measuring chamber 20 is provided on the outer wall surface of the chamber side portion 61 so as to cover the opening 23. Thus, the heat treatment space 65 of the chamber 6 and the atmosphere outside the apparatus do not directly communicate with each other.

The opening 23 is opened and closed by a gate valve 22. Specifically, when the gate valve 22 is moved by a driving mechanism not shown to open the opening 23, the interior space of the oxygen concentration measuring chamber 20 and the heat treatment space 65 of the chamber 6 are in communication with each other through the opening 23. On the other hand, when the gate valve 22 is moved by the driving mechanism to close the opening 23, the communication between the interior space of the oxygen concentration measuring chamber 20 and the heat treatment space 65 of the chamber 6 is closed off.

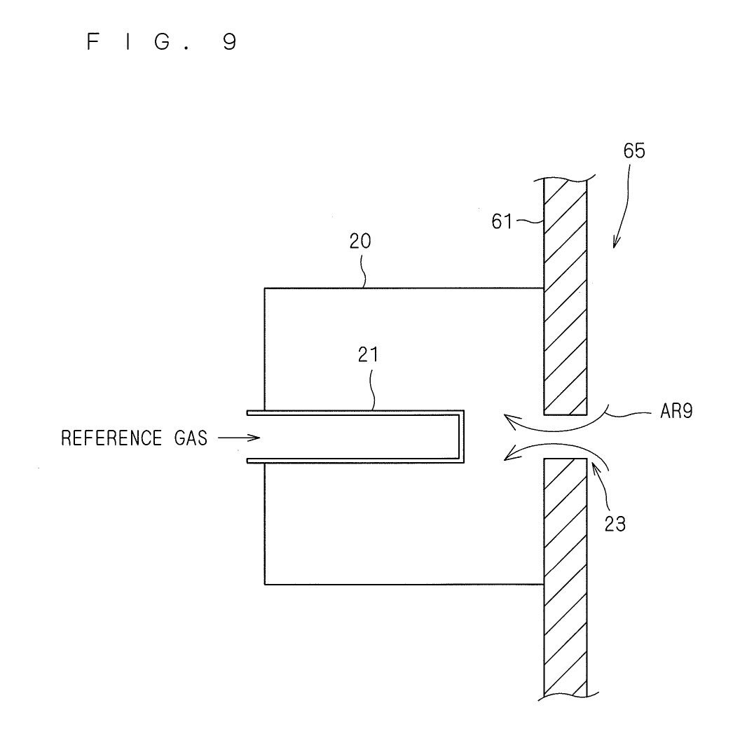

The oxygen concentration measuring chamber 20 is provided with the reference gas supply part 150, a calibration gas supply part 160, an inert gas supply part 170 and an exhaust part (second exhaust part) 140 attached thereto. The reference gas supply part 150 supplies a reference gas to the oxygen analyzer 21. The reference gas supply part 150 includes a reference gas supply source 151 and a valve 152. The reference gas supply source 151 supplies a standard gas having an oxygen concentration of 1 to 100 ppm as the reference gas. The standard gas is a gas having a known constituent concentration (oxygen concentration in the present preferred embodiment) and serving as a reference for concentration measurement. When the valve 152 is opened under the control of the controller 3, the reference gas having an oxygen concentration of 1 to 100 ppm is supplied from the reference gas supply source 151 to the interior of the oxygen analyzer 21 having a tubular shape with a bottom (with reference to FIG. 9).

The calibration gas supply part 160 supplies a calibration gas to the interior of the oxygen concentration measuring chamber 20. The calibration gas supply part 160 includes a calibration gas supply source 161 and a valve 162. The calibration gas supply source 161 supplies a gas having the same oxygen concentration as the aforementioned reference gas as the calibration gas. When the valve 162 is opened under the control of the controller 3, the calibration gas (i.e., a gas having an oxygen concentration of 1 to 100 ppm) is supplied from the calibration gas supply source 161 to the interior space of the oxygen concentration measuring chamber 20.

The inert gas supply part 170 supplies an inert gas to the interior of the oxygen concentration measuring chamber 20. The inert gas supply part 170 includes an inert gas supply source 171 and a valve 172. The inert gas supply source 171 supplies an inert gas such as nitrogen, argon and helium (nitrogen gas in the present preferred embodiment). When the valve 172 is opened under the control of the controller 3, the inert gas is supplied from the inert gas supply source 171 to the interior space of the oxygen concentration measuring chamber 20.

The exhaust part 140 exhausts a gas from the interior of the oxygen concentration measuring chamber 20. The exhaust part 140 includes an exhaust device 141 and a valve 142. When the valve 142 is opened while the exhaust device 141 is in operation under the control of the controller 3, the gas in the oxygen concentration measuring chamber 20 is exhausted to the exhaust device 141. The exhaust part 140 is capable of reducing the pressure in the oxygen concentration measuring chamber 20 at least to a level obtained during the pressure reduction in the heat treatment space 65 of the chamber 6 or lower.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct a flash of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along the main surface of a semiconductor wafer W held by the holder 7 (that is, in a horizontal direction). Thus, a plane defined by the arrangement of the flash lamps FL is also a horizontal plane.

Each of the xenon flash lamps FL includes a rod-shaped glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 is a light irradiator that directs light from under the chamber 6 through the lower chamber window 64 toward the heat treatment space 65 to heat the semiconductor wafer W by means of the halogen lamps HL.

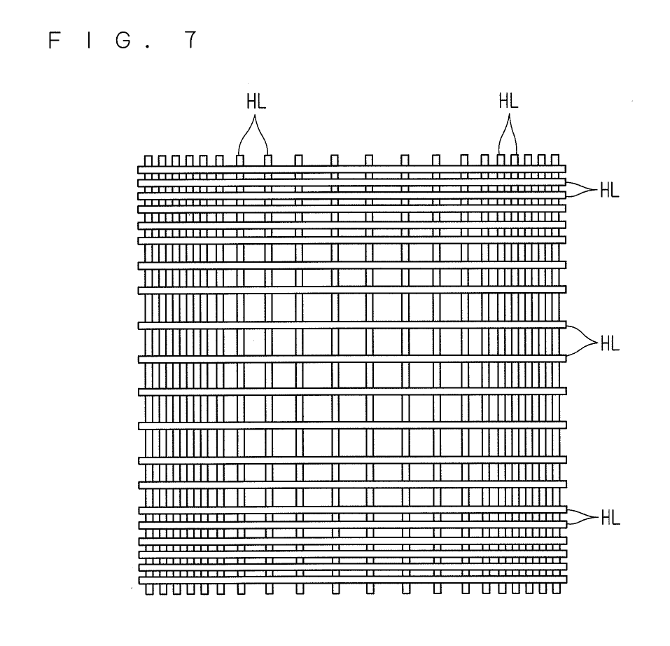

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in the upper tier and the 20 halogen lamps HL in the lower tier are arranged so that the longitudinal directions thereof are in parallel with each other along the main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to the peripheral portion of the semiconductor wafer W held by the holder 7 than in a region opposed to the central portion thereof. In other words, the halogen lamps HL in each of the upper and lower tiers are arranged at shorter intervals in the peripheral portion of the lamp arrangement than in the central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. Thus, the halogen lamps HL are continuously lighted lamps which emit light continuously at least for a time period of not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a magnetic disk for storing control software, data and the like therein. The CPU in the controller 3 executes a predetermined processing program, whereby the processes in the heat treatment apparatus 1 proceed. Also, the controller 3 controls the opening and closing of the gate valve 22 to cause the oxygen analyzer 21 to measure the concentration of oxygen in the atmosphere in the chamber 6.

The heat treatment apparatus 1 further includes, in addition to the aforementioned components, various cooling structures to prevent an excessive temperature rise in the halogen heating part 4, the flash heating part 5 and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

Next, a procedure for the treatment of a semiconductor wafer W in the heat treatment apparatus 1 will be described. A semiconductor wafer W to be treated herein is a semiconductor substrate on which a high dielectric constant film is formed as a gate insulator film. The heat treatment apparatus 1 irradiates the semiconductor wafer W with a flash of light to perform PDA (post deposition annealing) on the semiconductor wafer W. The procedure for the treatment in the heat treatment apparatus 1 to be described below proceeds under the control of the controller 3 over the operating mechanisms of the heat treatment apparatus 1.

First, the semiconductor wafer W to be treated is transported into the chamber 6 of the heat treatment apparatus 1. For the transport of the semiconductor wafer W into the chamber 6, the gate valve 185 is opened to open the transport opening 66. A transport robot outside the heat treatment apparatus 1 transports the semiconductor wafer W through the transport opening 66 into the heat treatment space 65 of the chamber 6. At this time, nitrogen gas may be continuously supplied from the treatment gas supply source 85 into the chamber 6 by opening the valve 84 to cause the nitrogen gas to flow outwardly through the transport opening 66, thereby minimizing the atmosphere outside the apparatus flowing into the chamber 6. The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the susceptor 74 to receive the semiconductor wafer W.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude. The semiconductor wafer W is held on the susceptor 74 in such an attitude that a surface thereof where the high dielectric constant film is formed is the upper surface. Also, the semiconductor wafer W is held inside the five guide pins 76 on the upper surface of the susceptor 74. The pair of transfer arms 11 moved downwardly below the susceptor 74 is moved back to the retracted position, i.e. to the inside of the recessed portion 62, by the horizontal movement mechanism 13.

After the semiconductor wafer W is received in the chamber 6 and the transport opening 66 is closed by the gate valve 185, the pressure in the chamber 6 is reduced to a pressure lower than atmospheric pressure. Specifically, the transport opening 66 is closed, so that the heat treatment space 65 of the chamber 6 becomes an enclosed space. In this state, the valve 89 for exhausting the gas is opened while the valve 84 for supplying the gas is closed. Thus, the gas is exhausted from the chamber 6 while the gas is not supplied into the chamber 6, so that the pressure in the heat treatment space 65 of the chamber 6 is reduced to less than atmospheric pressure. At the time of the start of the pressure reduction from atmospheric pressure, the opening 23 for the oxygen concentration measuring chamber 20 is closed by the gate valve 22. The pressure in the oxygen concentration measuring chamber 20 is reduced to the same level as the pressure in the chamber 6 by the exhaust part 140.

The pressure in the heat treatment space 65 becomes constant at the time when a predetermined time period has elapsed since the start of the pressure reduction in the chamber 6. The pressure is determined by the exhaust capability of the exhaust part 190 and the amount of gas leaking in trace amounts from the outside into the chamber 6. In the present preferred embodiment, the oxygen concentration in the atmosphere in the heat treatment space 65 is measured when the pressure in the chamber 6 is reduced to less than atmospheric pressure to enter a stable state. The time when the pressure in the chamber 6 is in the stable state refers to the time when the pressure in the chamber 6 is maintained constant.

After the pressure in the chamber 6 enters the stable state, the gate valve 22 opens the opening 23 under the control of the controller 3. This brings the interior space of the oxygen concentration measuring chamber 20 and the heat treatment space 65 of the chamber 6 into communication with each other through the opening 23.

FIG. 9 is a view of the opening 23 left open. When the opening 23 is opened, with the pressure in the chamber 6 maintained constant, to bring the interior space of the oxygen concentration measuring chamber 20 and the heat treatment space 65 of the chamber 6 into communication with each other through the opening 23, gas molecules are diffused from the heat treatment space 65 into the oxygen concentration measuring chamber 20, as indicated by arrows AR9 in FIG. 9. As a result, the atmosphere in the oxygen concentration measuring chamber 20 and the atmosphere in the heat treatment space 65 become homogeneous. In other words, the oxygen concentration in the oxygen concentration measuring chamber 20 becomes equal to that in the heat treatment space 65.

The zirconia type oxygen analyzer 21 provided in the oxygen concentration measuring chamber 20 is heated to a predetermined measurement temperature (generally in the range of 500 to 800° C.) by the heater not shown. The reference gas is supplied from the reference gas supply part 150 to the inside of the oxygen analyzer 21. The reference gas used in the present preferred embodiment is the standard gas having an oxygen concentration of 1 to 100 ppm.

When the reference gas having an oxygen concentration of 1 to 100 ppm is supplied to the inside of the oxygen analyzer 21 heated to the predetermined measurement temperature and the atmosphere outside the oxygen analyzer 21 is the same as the atmosphere in the heat treatment space 65, an electromotive force corresponding to a difference in oxygen concentration between the inside and the outside is produced at the wall surfaces of the tubular portion of the stabilized zirconia of the oxygen analyzer 21. The oxygen analyzer 21 measures the magnitude of the electromotive force to measure the oxygen concentration in the atmosphere in the oxygen concentration measuring chamber 20, i.e. the oxygen concentration in the atmosphere in the chamber 6. The result of measurement made by the oxygen analyzer 21 is transmitted to the controller 3. The controller 3 may display the measured oxygen concentration on a display panel and the like of the apparatus.

Next, with the pressure in the chamber 6 reduced, the 40 halogen lamps HL in the halogen heating part 4 turn on simultaneously to start the preheating (or assist-heating) of the semiconductor wafer W. Halogen light emitted from the halogen lamps HL is transmitted through the lower chamber window 64 and the susceptor 74 both made of quartz, and impinges upon the back surface of the semiconductor wafer W. The back surface of the semiconductor wafer W refers to a main surface thereof on the opposite side from the front surface with the high dielectric constant film formed thereon. The semiconductor wafer W is irradiated with the halogen light from the halogen lamps HL, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W is measured with the contact-type thermometer 130 when the halogen lamps HL perform the preheating. Specifically, the contact-type thermometer 130 incorporating a thermocouple comes through the notch 77 into contact with the lower surface of the semiconductor wafer W held by the susceptor 74 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL, based on the value measured with the contact-type thermometer 130, so that the temperature of the semiconductor wafer W is equal to the preheating temperature T1. The preheating temperature T1 is in the range of 300 to 700° C., and shall be 450° C. in the present preferred embodiment. It should be noted that, when the temperature of the semiconductor wafer W is increased by the irradiation with light from the halogen lamps HL, the temperature is not measured with the radiation thermometer 120. This is because the halogen light emitted from the halogen lamps HL enters the radiation thermometer 120 in the form of disturbance light to obstruct the precise measurement of the temperature.

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured with the contact-type thermometer 130 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in a peripheral portion thereof where heat dissipation is liable to occur than in a central portion thereof. However, the halogen lamps HL in the halogen heating part 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating. Further, the inner peripheral surface of the lower reflective ring 69 mounted to the chamber side portion 61 is provided as a mirror surface. Thus, a greater amount of light is reflected from the inner peripheral surface of the lower reflective ring 69 toward the peripheral portion of the semiconductor wafer W. This provides a more uniform in-plane temperature distribution of the semiconductor wafer W in the stage of preheating.

The flash lamps FL in the flash heating part 5 irradiate the front surface of the semiconductor wafer W with a flash of light at the time when a predetermined time period has elapsed since the temperature of the semiconductor wafer W reached the preheating temperature T1 because of the irradiation with light from the halogen lamps HL. At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

The flash heating, which is achieved by the emission of a flash of light from the flash lamps FL, is capable of increasing the temperature of the front surface of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The temperature of the front surface of the semiconductor wafer W which is flash heated by the irradiation with a flash of light from the flash lamps FL momentarily increases to a treatment temperature T2, so that the PDA of the high dielectric constant film formed on the front surface of the semiconductor wafer W is performed. The treatment temperature T2 that is the maximum temperature (peak temperature) reached by the front surface of the semiconductor wafer W subjected to the flash irradiation is in the range of 600 to 1200° C., and shall be 1000° C. in the present preferred embodiment.

When the halogen lamps HL perform the preheating of the semiconductor wafer W and the flash lamps FL perform the flash heating, the gate valve 22 may open the opening 23, so that the oxygen analyzer 21 measures the oxygen concentration in the chamber 6.

After a predetermined time period has elapsed since the completion of the flash heating treatment, the halogen lamps HL turn off. This causes the temperature of the semiconductor wafer W to decrease rapidly from the preheating temperature T1. Also, the nitrogen gas is supplied into the chamber 6 by opening the valve 84, so that the pressure in the chamber 6 is returned to atmospheric pressure. At this time, the gate valve 22 closes the opening 23 to close off the communication between the interior space of the oxygen concentration measuring chamber 20 and the heat treatment space 65 of the chamber 6. Also, nitrogen may be supplied from the inert gas supply part 170 into the oxygen concentration measuring chamber 20 to return the pressure in the oxygen concentration measuring chamber 20.

The radiation thermometer 120 or the contact-type thermometer 130 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 to the outside. Thus, the heat treatment apparatus 1 completes the heating treatment of the semiconductor wafer W.

In the present preferred embodiment, the oxygen concentration measuring chamber 20 is provided on the wall surface of the chamber 6, and the oxygen analyzer 21 is provided in the oxygen concentration measuring chamber 20. The opening 23 for bringing the interior space of the oxygen concentration measuring chamber 20 and the heat treatment space 65 of the chamber 6 into communication with each other therethrough is openable and closable by the gate valve 22. When the pressure in the chamber 6 is reduced to less than atmospheric pressure to enter a stable state, the gate valve 22 opens the opening 23, so that gas molecules in the chamber 6 are diffused into the oxygen concentration measuring chamber 20, and the oxygen concentration in the atmosphere in the chamber 6 is measured. This eliminates the influences of an airflow resulting from variations in pressure in the chamber 6 and a back diffusion from the exhaust system to achieve the precise measurement of the oxygen concentration in the atmosphere in the chamber 6 even when significant pressure variations are repeated in the chamber 6.

The reference gas with reference to which the oxygen analyzer 21 measures the oxygen concentration shall be the standard gas having an oxygen concentration of 1 to 100 ppm. Conventional zirconia type oxygen analyzers use the air (having an oxygen concentration of approximately 21%) as the reference gas in many cases. In such cases, the limit of measurement is approximately 1 ppm. The use of the standard gas having an oxygen concentration of 1 to 100 ppm as the reference gas as in the present preferred embodiment improves the limit of measurement of the oxygen concentration to approximately 0.1 ppm. As a result, the oxygen analyzer 21 is adaptable to processes in which a lower oxygen concentration is required.

When the standard gas having an oxygen concentration of 1 to 100 ppm is used as the reference gas, there are cases in which continued measurements for a long time result in an increased measurement error. It is hence preferable that the zero point setting of the oxygen analyzer 21 is made timely. Specifically, the gate valve 22 closes the opening 23, so that the interior space of the oxygen concentration measuring chamber 20 becomes an enclosed space. In this state, the calibration gas supply part 160 supplies a gas having the same oxygen concentration as the reference gas as the calibration gas into the oxygen concentration measuring chamber 20. While the oxygen analyzer 21 is heated to the predetermined measurement temperature and the reference gas is supplied from the reference gas supply part 150 to the inside of the oxygen analyzer 21 as in the measurement of the oxygen concentration, the gas having the same oxygen concentration as the reference gas is supplied as the calibration gas to the outside of the oxygen analyzer 21, so that the difference in oxygen concentration between the inside and the outside of the oxygen analyzer 21 becomes zero. This achieves the zero point setting of the oxygen analyzer 21 to improve the measurement accuracy of the oxygen analyzer 21. After the completion of the zero point setting operation, the exhaust part 140 exhausts the calibration gas from the oxygen concentration measuring chamber 20.

While the preferred embodiment according to the present invention has been described hereinabove, various modifications of the present invention in addition to those described above may be made without departing from the scope and spirit of the invention. For example, the oxygen analyzer 21 is fixedly provided in the oxygen concentration measuring chamber 20 in the aforementioned preferred embodiment. However, the oxygen analyzer 21 may be movable into and out of the chamber 6.

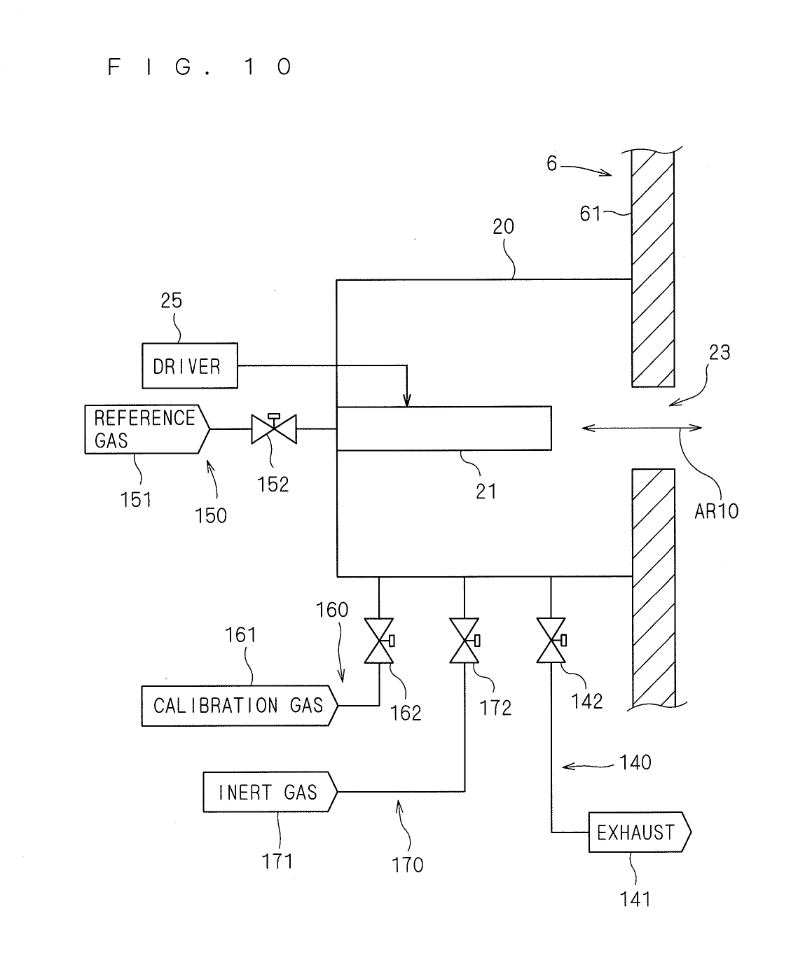

FIG. 10 is a view showing another configuration of the oxygen concentration measuring chamber 20. Like reference numerals and characters are used in FIG. 10 to designate components identical with those in the aforementioned preferred embodiment. The example of the configuration shown in FIG. 10 differs from that of FIG. 8 in the provision of a driver 25 for moving the oxygen analyzer 21 into and out of the chamber 6. Various known linear drive mechanisms such as an air cylinder and a ball screw mechanism may be used as the driver 25. When the opening 23 is open, the driver 25 moves the oxygen analyzer 21 into and out of the chamber 6, as indicated by an arrow AR10 in FIG. 10. When the oxygen analyzer 21 is moved into and out of the chamber 6, the tip of the oxygen analyzer 21 is inserted into and removed out of the chamber 6 through the opening 23.

In the aforementioned preferred embodiment, when the gate valve 22 opens the opening 23 during the measurement of the oxygen concentration, gas molecules are diffused from the heat treatment space 65 into the oxygen concentration measuring chamber 20. In the example of FIG. 10, when the opening 23 is opened during the measurement of the oxygen concentration, the tip of the oxygen analyzer 21 is inserted through the opening 23 into the heat treatment space 65 of the chamber 6. Thus, the oxygen concentration in the chamber 6 is measured more directly near the semiconductor wafer W.

In the aforementioned preferred embodiment, the PDA of the high dielectric constant film in which a low oxygen concentration is required is performed by the flash heating. However, the treatment performed by the flash heating of the heat treatment apparatus 1 is not limited to the PDA. For example, the activation of impurities implanted in the front surface of the semiconductor wafer W and the formation of silicides may be performed by the flash heating of the heat treatment apparatus 1. In particular, the technique according to the present invention is preferable for processes in which a low oxygen concentration is required.

Also, the flash heating is performed in the aforementioned preferred embodiment after the pressure in the chamber 6 is reduced to less than atmospheric pressure. However, the flash heating may be performed after nitrogen gas is supplied into the chamber 6 where the pressure is reduced once to return the pressure in the chamber 6 to atmospheric pressure. By reducing the pressure in the chamber 6 once to less than atmospheric pressure and thereafter supplying nitrogen into the chamber 6 to return the pressure in the chamber 6, the oxygen concentration in the chamber 6 is reduced as in the aforementioned preferred embodiment. In this case, after the oxygen concentration is measured in a reduced-pressure condition, the gate valve 22 closes the opening 23 to prevent the influence of a nitrogen gas flow from being exerted on the oxygen analyzer 21 during the return of the pressure. After the pressure in the chamber 6 is returned to atmospheric pressure to enter a stable state, the gate valve 22 may open the opening 23 again, so that the oxygen analyzer 21 measures the oxygen concentration in the atmosphere in the chamber 6.

The oxygen concentration measuring chamber 20 is provided on the outer wall surface of the chamber 6 in the aforementioned preferred embodiment. However, the oxygen concentration measuring chamber 20 may be provided inside a side wall of the chamber side portion 61. In this case, the opening 23 for bringing the interior space of the oxygen concentration measuring chamber 20 and the heat treatment space 65 of the chamber 6 into communication with each other therethrough is also opened and closed by the gate valve 22.

Also, a reactive gas may be introduced into the chamber 6, depending on the specifics of a process. However, there are cases in which the oxygen analyzer 21 cannot be used for some types of reactive gas. In such cases, the oxygen concentration is measured in the reduced-pressure condition before the introduction of the reactive gas, and the gate valve 22 closes the opening 23 during the introduction of the reactive gas to prevent the reactive gas from being diffused into the oxygen concentration measuring chamber 20.

Although the 30 flash lamps FL are provided in the flash heating part 5 according to the aforementioned preferred embodiment, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

While the invention has been described in detail, the foregoing description is in all aspects illustrative and not restrictive. It is understood that numerous other modifications and variations can be devised without departing from the scope of the invention.

What is claimed is:

1. A heat treatment apparatus for irradiating a substrate with a flash of light to heat the substrate, comprising:
a chamber for receiving a substrate therein;
a flash lamp for irradiating said substrate received in said chamber with a flash of light;
a first exhaust part for exhausting an atmosphere from said chamber;
a treatment gas supply part for supplying a predetermined treatment gas to said chamber;
a measuring chamber provided on a wall surface of said chamber;
a zirconia type oxygen analyzer provided in said measuring chamber;
a gate valve for opening and closing an opening for bringing the interior of said measuring chamber and the interior of said chamber into communication with each other therethrough; and
a controller for controlling the opening and closing of said gate valve, said controller being configured to open said gate valve when the pressure in said chamber is in a stable state.

2. The heat treatment apparatus according to claim 1, wherein
said controller is configured to open said gate valve when the pressure in said chamber is reduced to less than atmospheric pressure by said first exhaust part.

3. The heat treatment apparatus according to claim 1, further comprising
a reference gas supply part for supplying a reference gas having an oxygen concentration of 1 to 100 ppm to said zirconia type oxygen analyzer.

4. The heat treatment apparatus according to claim 3, further comprising:
a calibration gas supply part for supplying a gas having the same oxygen concentration as said reference gas to said measuring chamber; and
a second exhaust part for exhausting an atmosphere from said measuring chamber.

5. The heat treatment apparatus according to claim 4, further comprising
an inert gas supply part for supplying an inert gas to said measuring chamber.

6. The heat treatment apparatus according to claim 1, further comprising
a moving mechanism for moving said zirconia type oxygen analyzer into and out of said chamber when said gate valve is open.
